(19) United States
(12) Patent Application Publication
(10) Pub. No.: US 2003/0183888 A1
(43) Pub. Date: Oct. 2, 2003

(54) Corrugated diaphragm

(76) Inventors: Eyal Bar-Sadeh, Jerusalem (IL); Guy Berliner, Modi'in (IL)

Correspondence Address: SCHWEGMAN, LUNDBERG, WOESSNER & KLUTH, P.A., P.O. BOX 2938, MINNEAPOLIS, MN, 55402, US

(21) Appl. No.: 10/112,072

(22) Filed: Mar. 28, 2002

(51) Int. Cl. H01L 21/00

(52) U.S. Cl. 257/419

(57) ABSTRACT

A diaphragm includes a substrate having a hole and a sheet of material formed on the substrate and covering the hole. The sheet of material includes one or more corrugations that are substantially free of defects. A method of forming the diaphragm includes forming a corrugated surface free of stringers on the substrate, forming a layer of material on the corrugated surface, and processing the substrate to form the diaphragm including the layer of material.

### FIELD

This invention relates to microelectromechanical systems (MEMS) and, more particularly, to a corrugated diaphragm fabricated using MEMS technology.

### BACKGROUND

A diaphragm can sense acoustic waves. Systems, such as communication systems and pressure measurement systems, use microelectricalmechanical system diaphragms as a building block for sensing acoustic waves. Some customers who purchase such systems require that each new system be capable of sensing acoustic waves having less energy than the acoustic waves sensed by the previous system. Designing and fabricating a more sensitive diaphragm for each new system is one approach to meeting this requirement.

A thin, corrugated diaphragm is more sensitive than a thin, flat diaphragm for sensing low energy acoustic waves. Unfortunately, efficiently fabricating a thin, corrugated diaphragm presents a difficult problem. Any defect on a surface on which the thin, corrugated diaphragm is formed can cause defects, such as a holes or deformations, in the surface of the diaphragm. Such defects may go unnoticed in a thick diaphragm, but in a thin diaphragm these defects can prevent the diaphragm from performing at the desired sensitivity level.

Corrugated diaphragms can be formed by depositing material on the surface of a substrate having etched grooves that define the corrugations in the diaphragm. The sides of the grooves can include stringers, which are thin shards or strands of substrate material that extend out from the sides of the grooves. Stringers are a byproduct of the process of etching grooves in the substrate and are common in grooves etched in silicon substrates. Diaphragms formed on a substrate surface that includes grooves having stringers often have defects, such as holes and deformations, which are caused by the stringers. The holes and deformations decrease the sensitivity of the diaphragm.

For these and other reasons there is a need for the present invention.

### BRIEF DESCRIPTION OF THE DRAWINGS

FIG. 1A shows a perspective view of a diaphragm in accordance with one embodiment of the invention.

FIG. 1B shows a cross-sectional view of the diaphragm shown in FIG. 1A taken along the line XX.

FIG. 2 shows a flow diagram of a method for forming a diaphragm in accordance with one embodiment of the invention.

FIG. 3 shows a flow diagram of a method for forming a diaphragm in accordance with an alternate embodiment of the invention.

FIGS. 4A, 4B, 4C, 4D, 4E, 4F, 4G, 4H, 4I, 4J, 4K, 4L, 4M, 4N, and 40 show a sequence of cross-sectional views of a substrate after each of a series of processing operations in a method for forming a diaphragm in accordance with another alternate embodiment of the invention.

FIG. 5 shows a diaphragm deflection detector system in accordance with one embodiment of the invention.

### DESCRIPTION

In the following detailed description of the invention, reference is made to the accompanying drawings which form a part hereof, and in which are shown, by way of illustration, specific embodiments of the invention which may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is not to be taken in a limiting sense, and the scope of the present invention is defined only by the appended claims, along with the full scope of equivalents to which such claims are entitled.

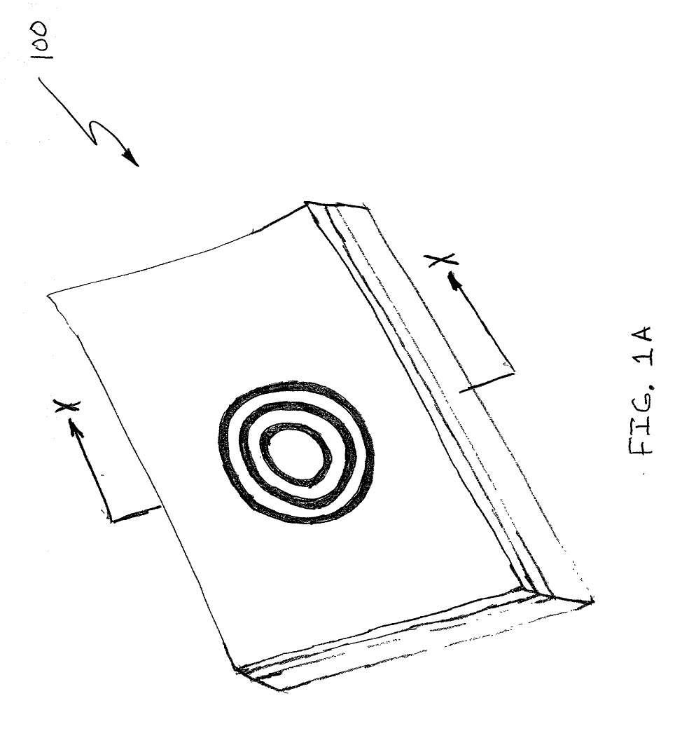

FIG. 1A shows a perspective view of a diaphragm 100 in accordance with one embodiment of the invention.

FIG. 1B shows a cross-sectional view of the diaphragm 100 shown in FIG. 1A taken along the line XX. The diaphragm 100 includes a substrate 102 having a hole 104 and a sheet of material 106 that covers the hole 104.

The substrate 102 provides a surface 107 on which the sheet of material 106 can be formed or deposited. The substrate 102 is not limited to a particular material. Materials suitable for use in connection with the fabrication of the substrate 102 in the diaphragm 100 include materials that can be processed using integrated circuit manufacturing techniques and processes. Semiconductors are one class of substrate materials suitable for use in connection with the fabrication of the diaphragm 100. In one embodiment, the substrate 102 is silicon. In an alternate embodiment, the substrate 102 is germanium. In another alternate embodiment, the substrate 102 is gallium arsenide. In still another embodiment, the substrate 102 is silicon-on-sapphire.

The hole 104 provides an area over which the sheet of material 106 can vibrate or oscillate in response to acoustic waves. The hole 104 is a depression, indentation, hollowed-out volume, or opening through the substrate 102. The hole 104 includes a perimeter 108 that defines the shape of the hole at the surface 107 of the substrate 102. The perimeter 108 is not limited to a defining a particular shape. In one embodiment, the perimeter 108 defines a substantially circular shape. In an alternate embodiment, the perimeter 108 defines a substantially elliptical shape. In another alternate embodiment, the perimeter 108 defines a substantially rectangular shape. In still another alternate embodiment, the perimeter 108 defines a substantially square shape. In yet another alternate embodiment, the perimeter 108 defines a substantially triangular shape.

The sheet of material 106 is formed on the surface 107 of the substrate 102 and covers the hole 104. The sheet of material 106 is not limited to a particular material. Materials suitable for use in the fabrication of the sheet of material 106 include materials used in the fabrication of integrated circuits. In one embodiment, the sheet of material 106 is silicon nitride. In an alternate embodiment, the sheet of material 106 is silicon.

The sheet of material 106 has a thickness 112. The thickness 112 is not limited to a particular value, however a thin sheet of material is more sensitive to low energy acoustic vibrations than a thick sheet of material. In one embodiment, the sheet of material 106 has a thickness 112 of between about 50 nanometers and about 100 nanometers. A sheet of material having a thickness of less than about 50 nanometers is difficult to manufacture efficiently. A sheet of material having the thickness greater than about 100 nanometers is not as sensitive to low energy acoustic vibrations as a sheet of material having a thickness of more than about 50 nanometers and less than about 100 nanometers.

Since the diaphragm 100 can be used in a variety of applications, including some that do not require the acoustic sensitivity provided by a sheet of material having a 50 nanometer thickness, the specification in a particular application for the thickness 112 of the sheet of material 106 can be greater than 100 nanometers. Thus, the diaphragm 100 can be formed from the sheet of material 106 having a thickness greater than 100 nanometers. In one embodiment, the sheet of material 106 has a thickness 112 of between about 100 nanometers and about 200 nanometers. In an alternate embodiment, the sheet of material 106 has a thickness 112 of between about 200 nanometers and about 500 nanometers.

The sheet of material 106 includes an area 114 that covers the hole 104. The area 114 includes one or more corrugations 116 that are substantially free of defects. A defect is any indentation, deformation, hole or other structure or void that decreases the smoothness of the surface of the one or more corrugations 116.

The one or more corrugations 116 include ridges and grooves. The one or more corrugations 116 are not limited to a particular number of ridges and grooves. An exemplary ridge 118 and an exemplary groove 120 are shown in FIG. 1B. The ridge 118 is a crest in the one or more corrugations 116, and the groove 120 is a narrow channel or depression in the one or more corrugations 116. The groove 120 has a depth 122, however the groove 120 is not limited to a particular depth. The depth 122 is the vertical distance between the ridge 118 and the groove 120. In one embodiment, the groove 120 has a depth 122 of more than about 50 nanometers.

The one or more corrugations 116 are not limited to a particular shape or to a particular combination of shapes. Exemplary shapes for the ridge 118 and the groove 120 include open shapes and closed shapes. Exemplary open shapes include linear or straight shapes, such as straight lines, and curved shapes, such as half-circles or partial ellipses. Exemplary closed shapes include shapes such as circles or squares. In one embodiment, the one or more corrugations 116 are composed of two or more concentric rings, as shown in FIGS. 1A and 1B.

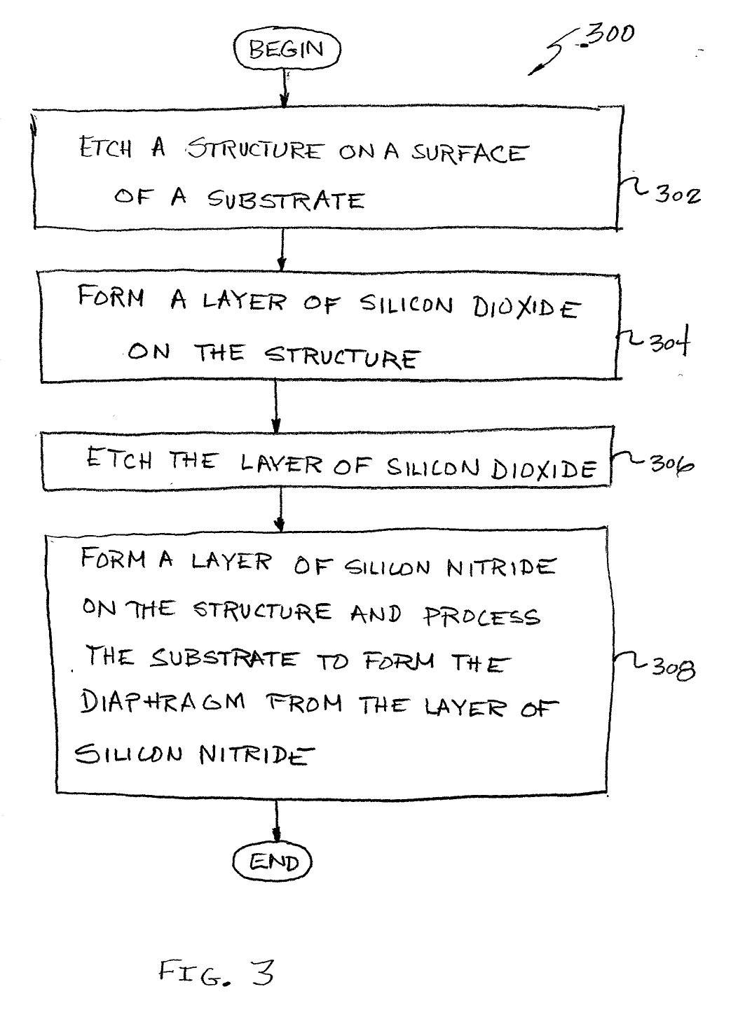

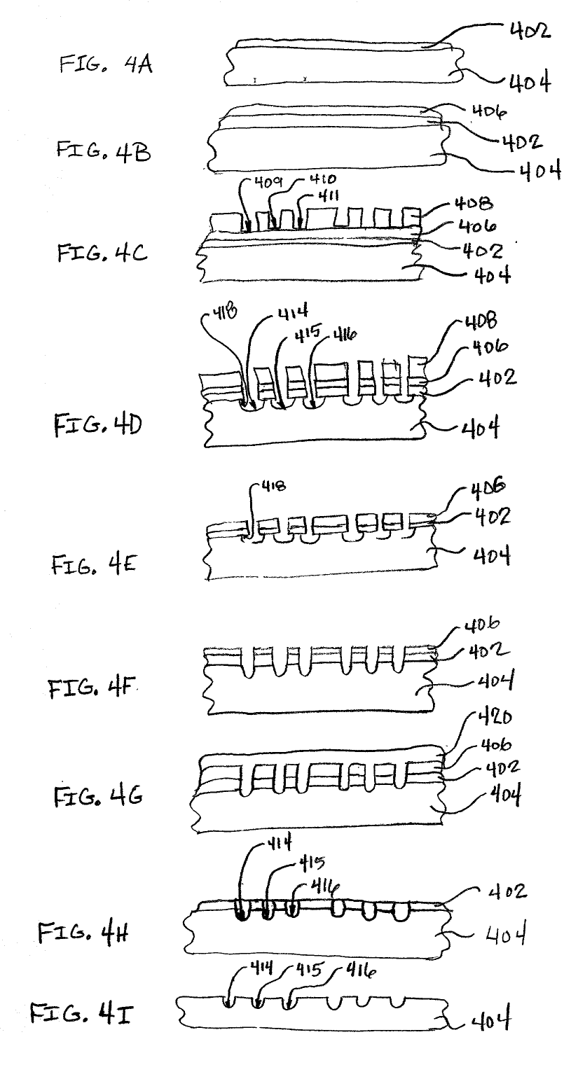

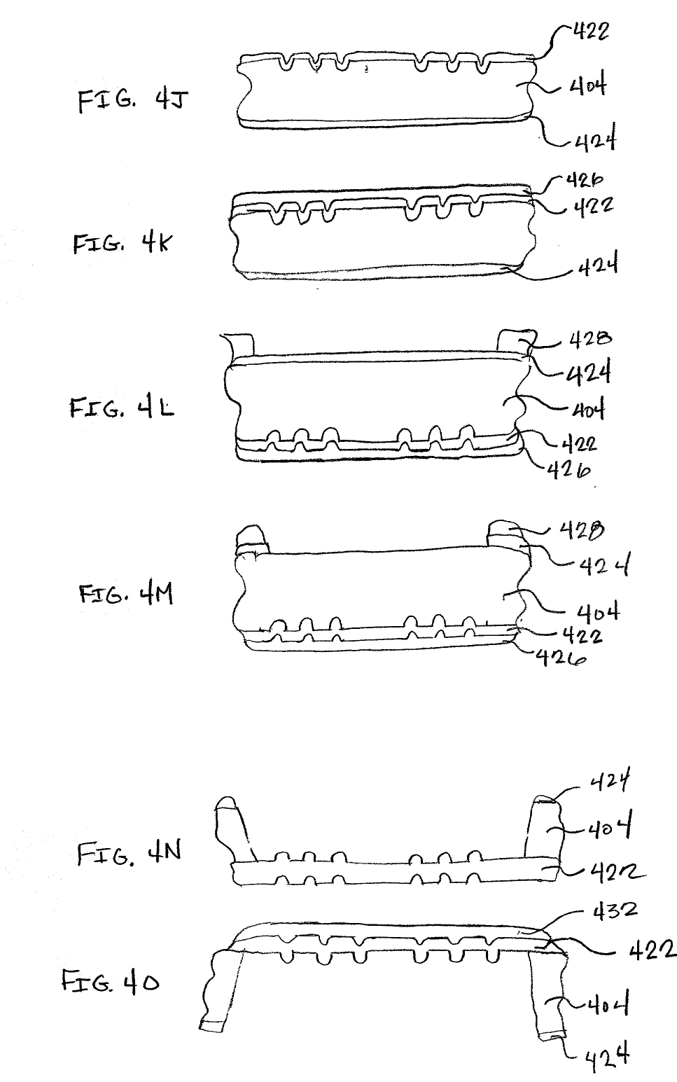

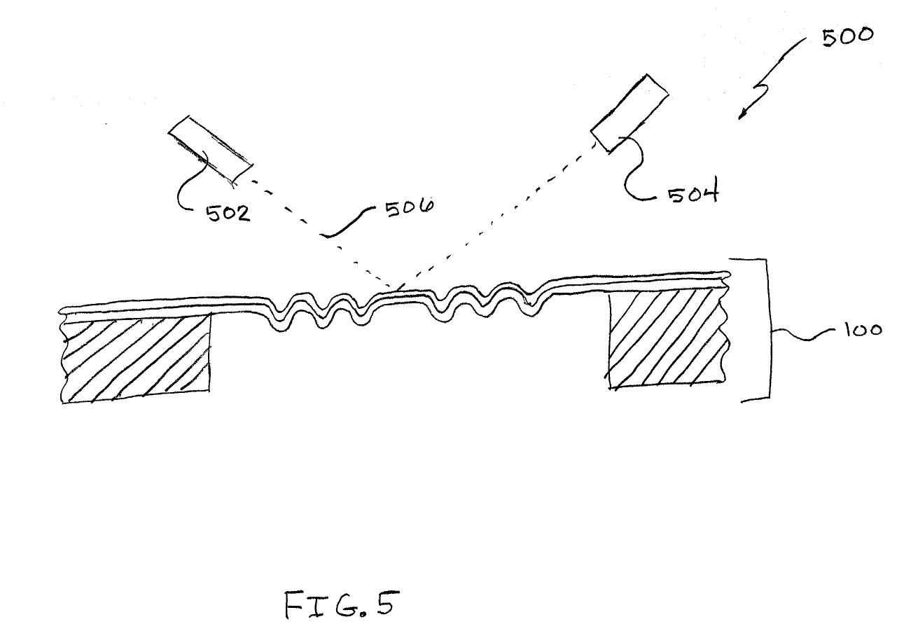

The sheet of material 106 includes a surface 124 coated with a reflective material 126. The reflective material 126 provides a surface for the diaphragm 100 that can be optically tracked (shown in FIG. 4) as the sheet of material 106 vibrates or oscillates. The reflective material 126 is not limited to a particular reflective material. In one embodiment, the reflective material 126 is gold. In an alternate embodiment, the reflective material 126 is aluminum. In another alternate embodiment, the reflective material 126 is silver.

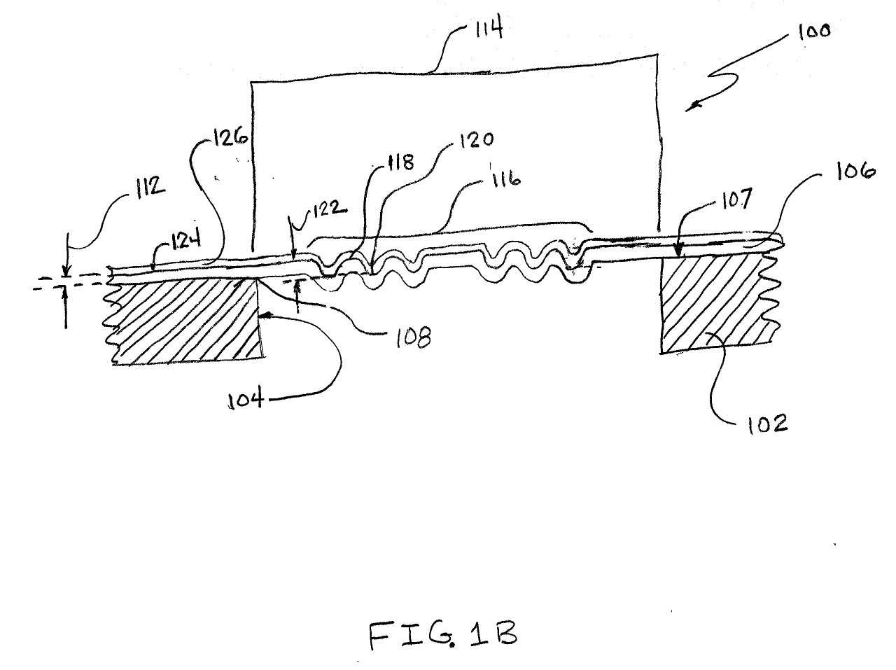

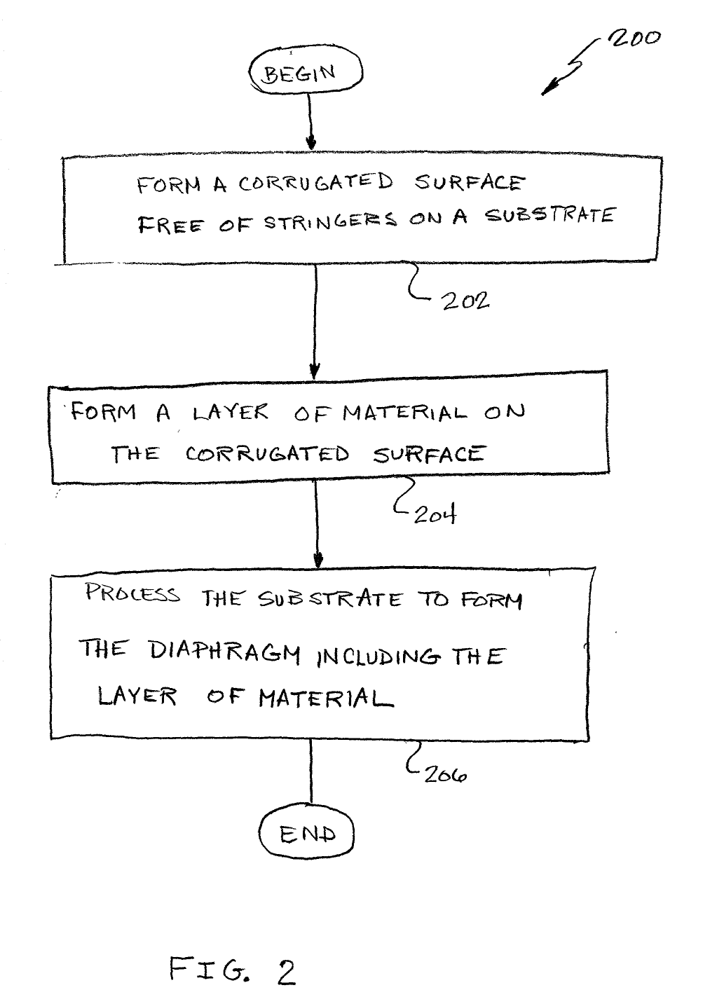

FIG. 2 shows a flow diagram of a method 200 for forming a diaphragm in accordance with one embodiment of the invention. The method 200 includes forming a corrugated surface free of stringers (stringers are thin shards or strands of substrate material that extend from the sides or bottoms of etched grooves and stand out above the average surface topography) on a substrate (block 202), forming a layer of material on the corrugated surface (block 204), and processing the substrate to form the diaphragm including the layer of material (block 206). In an alternate embodiment, forming a corrugated surface free of stringers on a substrate includes etching one or more grooves on the substrate, forming a layer of sacrificial material on the substrate, and etching the layer of sacrificial material. In another alternate embodiment, forming a layer of sacrificial material on the substrate includes forming a layer of silicon dioxide on the substrate. In still another alternate embodiment, forming a layer of material on the corrugated surface includes forming a layer of silicon nitride on the corrugated surface.

FIG. 3 shows a flow diagram of a method 300 for forming a diaphragm in accordance with an alternate embodiment of the invention. The method 300 includes etching a structure on a surface of a substrate (block 302), forming a layer of silicon dioxide on the structure (block 304), etching the layer of silicon dioxide (block 306), and forming a layer of silicon nitride on the structure and processing the substrate to form the diaphragm from the layer of silicon nitride (block 308). In an alternate embodiment, etching a structure on a surface of the substrate includes plasma etching the structure on the surface of a substrate. In another alternate embodiment, etching a layer of silicon dioxide includes plasma etching the layer of silicon dioxide.

FIGS. 4A, 4B, 4C, 4D, 4E, 4F, 4G, 4H, 4I, 4J, 4K, 4L, 4M, 4N, and 40 show a sequence of cross-sectional views of a substrate after each of a series of processing operations in a method for forming a diaphragm in accordance with another alternate embodiment of the invention.

Operation A: Form a sacrificial oxide layer 402 on a silicon substrate 404. (FIG. 4A)

Operation B: After operation A, form a silicon-nitride layer 406 on the sacrificial oxide layer 402. (FIG. 4B)

Operation C: After operation B, pattern a resist 408 on the silicon nitride layer 406 to define corrugations sites 409, 410, and 411. (FIG. 4C)

Operation D: After operation C, etch to form corrugations 414, 415, and 416 in the silicon substrate 404. (FIG. 4D)

At the completion of operation D, the corrugations 414-416 have been formed, but one or more undesired silicon nitride shelves 418, which are subsequently removed, have also been formed.

Operation E: After operation D, strip the resist 408 and clean. (FIG. 4E)

Operation F: After operation E, partially etch the silicon nitride layer 406 to remove the one or more silicon nitride shelves 418. (FIG. 4F)

At the completion of operation F, the one or more silicon nitride shelves 418 have been removed.

Operation G: After operation F, form a sacrificial silicon dioxide layer 420. (FIG. 4G)

Operation H: After operation G, etch to remove the silicon nitride layer 406 leaving the sacrificial oxide layer 402. The corrugations 414, 415, and 416 are still filled with the silicon dioxide deposited during the formation of the sacrificial silicon dioxide layer 420. (FIG. 4H)

Operation I: After operation H, etch to remove the sacrificial oxide layer 402 from the surface of the silicon substrate 404 and the sacrificial silicon dioxide layer 420 from the corrugations 414, 415, and 416. (FIG. 4I)

At the completion of operation I, the corrugations 414, 415, and 416 are clear of the sacrificial silicon dioxide layer 420 and the corrugations 414, 415, and 416 have smooth surfaces free of stringers.

Operation J: After operation I, form a front side silicon nitride layer 422 and a back side silicon nitride layer 424. (FIG. 4J)

Operation K: After operation J, form a silicon dioxide layer 426. (FIG. 4K)

Operation L: After operation K, pattern a resist 428 to define a square on the back side silicon nitride layer 424. (FIG. 4L)

Operation M: After operation L, etch to remove the patterned back side silicon nitride layer 424 in the square. (FIG. 4M)

Operation N: After operation M, etch to remove the silicon dioxide layer 426 and silicon from the silicon substrate 404 leaving the silicon nitride layer 422 suspended from the silicon substrate 404. The silicon nitride layer 422 is suspended from the silicon substrate 404 when a portion of the silicon nitride layer 422 is free to vibrate unencumbered by contact with the silicon substrate 404. (FIG. 4N)

At the completion of operation N, silicon has been removed from the silicon substrate 404, and the silicon nitride layer 422 is suspended from the silicon substrate 404.

Operation O: After operation N, flip the silicon substrate 404 and sputter a gold layer 432 on one or more surfaces of the silicon nitride layer 422. (FIG. 40)

At the completion of operation O, the silicon nitride layer 422 which is suspended from the silicon substrate 404 has been coated on one or both sides with the gold layer 432 and the fabrication of the diaphragm 100 is complete.

FIG. 5 shows an illustration of a diaphragm deflection detector system 500 in accordance with one embodiment of the invention. The diaphragm deflection detector system 500 includes a signal source 502, a diaphragm 100 (shown in FIG. 1), and a detector 504.

The signal source 502 generates a signal 506 that is reflected at the diaphragm 100 and received at the detector 504. The signal source 502 is not limited to a particular type of signal source. Exemplary signal sources suitable for use in connection with the diaphragm deflection detector system 500 include electromagnetic signal sources, such as lasers, masers, and light-emitting diodes. Exemplary lasers suitable for use in connection with the diaphragm deflection detector system 500 include solid-state lasers and gas lasers. In one embodiment, the signal source 502 is a semiconductor laser. In an alternate embodiment, the signal source 502 is a gas laser. In still another alternate embodiment the signal source 502 is a gallium arsenide light-emitting diode. In yet another alternate embodiment, the signal source 502 is an aluminum gallium arsenide light-emitting diode.

The detector 504 detects the signal generated by the signal source 502 and reflected from the diaphragm 100. The detector 504 is selected to detect the signal 506 after it is reflected from the diaphragm 100. The spectrum of the reflected signal is determined from the spectrum of the signal source 502 and the reflectivity of the diaphragm 100. Since the diaphragm 100 vibrates or oscillates during operation, the detector 504 should be capable of detecting linear movement of the signal 506. In one embodiment, the detector 504 is a linear diode array. A linear diode array includes a plurality of substantially identical diodes arranged in a line. A linear diode array can be fabricated on a single die in order to ensure substantially identical diodes. Die materials suitable for use in connection with the detector 504 include silicon, germanium, and gallium arsenide. Exemplary diode arrays suitable for use in connection with the diaphragm deflection detector system 500 include arrays having 1024, 2048 or 4096 diodes. In an alternate embodiment, the detector 504 is a charge-coupled device. In another alternate embodiment, the detector 504 is a charge-coupled device having a two-dimensional array of electromagnetic radiation sensing elements. In a charge-coupled device, the electromagnetic radiation sensing elements are coupled together and the charge accumulated in one device is shifted out of the device through other devices. A two-dimensional charge-coupled device permits tracking the signal 506 in two dimensions.

Although specific embodiments have been described and illustrated herein, it will be appreciated by those skilled in the art, having the benefit of the present disclosure, that any arrangement which is intended to achieve the same purpose may be substituted for a specific embodiment shown. This application is intended to cover any adaptations or variations of the present invention. Therefore, it is intended that this invention be limited only by the claims and the equivalents thereof.

What is claimed is:

1. A diaphragm comprising:
a sheet of material formed on a substrate having a hole, the sheet of material covering the hole and including one or more corrugations that are substantially free of defects.

2. The diaphragm of claim 1, wherein the sheet of material has a thickness of between about 50 nanometers and about 100 nanometers.

3. The diaphragm of claim 2, wherein the sheet of material comprises silicon nitride.

4. The diaphragm of claim 3, wherein the hole has a substantially circular perimeter.

5. The diaphragm of claim 4, wherein the one or more corrugations comprise two or more concentric rings.

6. The diaphragm of claim 5, wherein the one or more corrugations includes a groove having a depth of more than about 50 nanometers.

7. The diaphragm of claim 6, wherein the substrate comprises silicon.

8. The diaphragm of claim 1, wherein the sheet of material comprises one surface coated with a reflective material.

9. The diaphragm of claim 8, wherein the reflective material comprises gold.

10. A method of forming a diaphragm, comprising:
forming a corrugated surface free of stringers on a substrate;
forming a layer of material on the corrugated surface; and
processing the substrate to form the diaphragm including the layer of material.

11. The method of claim 10, wherein forming the corrugated surface free of stringers on the substrate comprises:
etching one or more grooves on the substrate;
forming a layer of sacrificial material on the substrate; and
etching the layer of sacrificial material.

12. The method of claim 11, wherein forming the layer of sacrificial material on the substrate comprises:
forming a layer of silicon dioxide on the substrate.

13. The method of claim 12, wherein forming the layer of material on the corrugated surface comprises:
forming a layer of silicon nitride on the corrugated surface.

14. A method of forming a diaphragm, comprising:
etching a structure on a surface of a substrate;
forming a layer of silicon dioxide on the structure;
etching the layer of silicon dioxide; and
forming a layer of silicon nitride on the structure and processing the substrate to form the diaphragm from the layer of silicon nitride.

15. The method of claim 14, wherein etching the structure on the surface of the substrate comprises:
plasma etching the structure on the surface of a substrate.

16. The method of claim 15, wherein etching the layer of silicon dioxide comprises: plasma etching the layer of silicon dioxide.

17. A method for detecting an acoustic wave comprising:
receiving an acoustic wave at a diaphragm including a sheet of material formed on a substrate having a hole, the sheet of material covering the hole and including one or more corrugations that are substantially free of defects; and
detecting a deflection of the sheet of material.

18. The method of claim 17, wherein detecting the deflection of the sheet of material comprises detecting a signal reflected from the sheet of material.

19. The method of claim 18, wherein detecting the signal reflected from the sheet of material comprises detecting the signal at a charge-coupled device.
